(19) United States
(12) Patent Application Publication
(10) Pub. No.: US 2017/0060282 A1
(43) Pub. Date: Mar. 2, 2017

(54) METHOD OF SELECTIVELY ETCHING A METAL LAYER FROM A MICROSTRUCTURE

(71) Applicant: 3M INNOVATIVE PROPERTIES COMPANY, St. Paul, MN (US)

(72) Inventor: Muthu Sebastian, Singapore (SG)

(21) Appl. No.: 15/120,576

(22) PCT Filed: Jan. 30, 2015
(86) PCT No.: PCT/US2015/013676

§ 371 Date: Aug. 22, 2016

Related U.S. Application Data
(60) Provisional application No. 61/970,101, filed on Mar. 25, 2014.

(51) Int. Cl. G06F 3/041; H05K 3/06; C23F 1/32

(52) U.S. Cl. CPC G06F 3/041; C23F 1/32; H05K 3/067; H05K 3/061; G06F 2203/04103; H05K 2203/0793

(57) ABSTRACT

The invention relates to a method of etching a portion of a metal layer of a microstructure comprised of the metal layer disposed on a transparent conducting oxide (TCO) layer, and in particular, to selectively etching the portion of the metal layer and not the TCO layer.

### TECHNICAL FIELD

The invention relates to a method of etching a portion of a metal layer of a microstructure comprised of the metal layer disposed on a transparent conducting oxide (TCO) layer, and in particular, to selectively etching a portion of the metal layer and not the TCO layer.

### BACKGROUND

Touch screen panels are now ubiquitous and commonly used as the input and display interface, for example, in automatic teller machines, gambling machines in casinos, mobile communication devices, and navigation units. Touch screen panels generally comprise a transparent base substrate (for example, glass or polyethylene terephthalate (PET)) and a transparent conductive pattern (for example, indium tin oxide (ITO)) disposed on the base substrate. Patterned conductive metal (for example, copper or silver) is then formed on the edges of the transparent conductive pattern to provide a bus bar and to reduce the resistivity of the device.

Conductive metal pattern is typically applied using a conductive adhesive to adhere the conductive metal pattern and the transparent conductive pattern. In such a case, resistivity increases over a period of time as the conductive adhesive fails at high temperature and humidity. Other existing methods, such as silver frit, are costly and require special expensive indium solder in order to attach wires thereto. Electro deposition of conductive metals is not feasible because of the poor current carrying capacity of the transparent conductive pattern material (e.g., ITO). Similarly, electroless deposition of metals is challenging as the chemicals necessary in the plating bath undergo undesirable side reactions with the transparent conductive pattern material, frequently leading to etching of the transparent conductive pattern material during plating. Silver ink printing on the transparent conductive pattern material (e.g. ITO) is widely used to provide the bus bar. This method is very expensive and may not be suitable for fine pitch patterning.

Therefore, there remains a need to provide a patterning method that overcomes, or at least alleviates, the above problems.

### SUMMARY

According to an aspect of the invention, there is provided a method of selectively etching a portion of a metal layer of a microstructure, wherein the microstructure is comprised of the metal layer disposed on a transparent conducting oxide (TCO) layer. The method includes contacting the microstructure with an etchant formulation. The etchant formulation includes a mixture of cupric halide and a solution of an amine and/or ammonium compound.

### BRIEF DESCRIPTION OF THE DRAWINGS

In the drawings, like reference characters generally refer to the same parts throughout the different views. The drawings are not necessarily drawn to scale, emphasis instead generally being placed upon illustrating the principles of various embodiments. In the following description, various embodiments of the invention are described with reference to the following drawings, in which:

FIG. 1A is a plan view of a patterned microstructure;

FIG. 1B is a cross-sectional view of the microstructure of FIG. 1A;

FIG. 1C is a cross-sectional view of the microstructure of FIG. 1A illustrating both sides of substrate 12;

FIG. 2 illustrates a method of etching metal layer and conductor simultaneously;

FIG. 3 illustrates a method of selectively etching a metal layer of a microstructure;

FIG. 4 illustrates the relative change in sheet resistance versus pH of ammonium hydroxide in the etchant formulation in one example;

FIG. 5 illustrates the relative change in sheet resistance versus concentration of ammonium chloride in the etchant formulation in one example;

FIG. 6 illustrates the transmittance spectra of the TCO layer after selectively etching of the metal layer of the microstructure; and

FIG. 7 is a photograph of touch view panel showing the transparent conductor on the view area and the copper bezel on the non-view area.

### DESCRIPTION

The following detailed description refers to the accompanying drawings that show, by way of illustration, specific details and embodiments in which the invention may be practiced. These embodiments are described in sufficient detail to enable those skilled in the art to practice the invention. Other embodiments may be utilized and structural, logical, and electrical changes may be made without departing from the scope of the invention. The various embodiments are not necessarily mutually exclusive, as some embodiments can be combined with one or more other embodiments to form new embodiments.

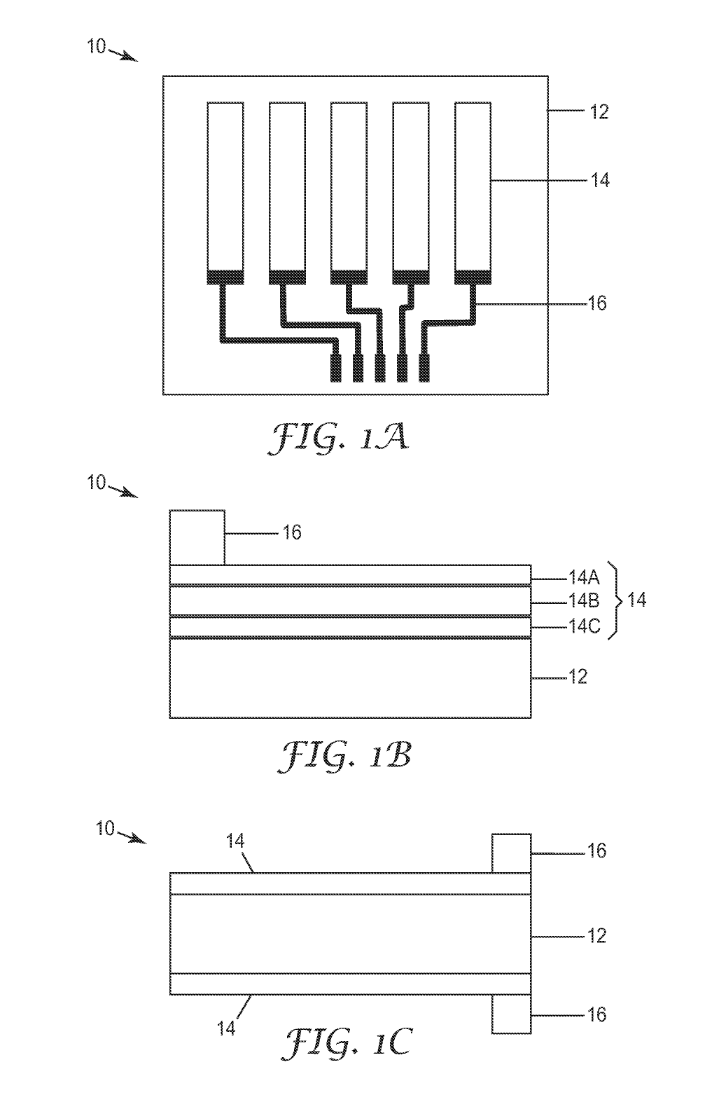

FIG. 1A provides a plan view of a patterned microstructure 10 in accordance with various embodiments. The microstructure 10 may be made up of a flexible substrate 12, a conductor 14 and a metal layer 16. The substrate 12, the conductor 14 and the metal layer 16 may be arranged such that the conductor 14 is disposed on the substrate 12 and the metal layer 16 may be disposed on the conductor 14. The microstructure 10 may form part of a touch screen panel, for example.

For the sake of the present discussion and for brevity, while the microstructure 10 may be referred to as made up of a substrate 12, a conductor 14 and a metal layer 16, it is to be understood and appreciated by a skilled person in the art that one or more of the respective components may be included as well. For example, in the illustration shown in FIG. 1A, a plurality of conductors 14 are disposed on the substrate 12 and a plurality of metal layers 16 are disposed on the conductors 14. As shown, the plurality of conductors 14 are disposed apart from one another and the plurality of metal layers 16 are disposed apart from one another. In preferred embodiments, the number of conductors 14 corresponds to the number of metal layers 16. In other embodiments, the number of conductors 14 does not correspond to the number of metal layers 16.

FIG. 1B provides a cross-sectional view of the microstructure 10 of FIG. 1A. In various embodiments, the conductor 14 may be disposed on two opposing major surfaces of the substrate 12 of the microstructure 10. Likewise, the metal layer 16 may be disposed on the conductor 14 disposed on two opposing major surfaces of the substrate 12 of the microstructure 10. A portion of the metal layer 16 may be disposed on the conductor 14 in the touch sensor view area/end of the electrode 14, while another portion of the metal layer 16 may be disposed on the conductor 14 in the touch sensor interconnect area of substrate 12 (i.e. metal layer 16 on touch sensor view area has dimension similar to touch sensor electrodes 14, while metal layer on interconnect area has narrow pitch density ranging from 30/30 μm pitch to 150/150 μm pitch and terminated with bonding pads with broader pitch density typically 150/150 um or more in accordance with the connectors used in the touch sensor assembly) as illustrated in FIGS. 1A & 1B. The arrangement of the conductor 14 and the metal layer 16 on the two opposing major surfaces of the substrate 12 may be suitable for applications where dual-side touch screen panels are desired, for example. In other embodiments, the conductor 14 and the metal layer 16 may be disposed only on one surface of the substrate 12 of the microstructure 10.

In various embodiments illustrated in FIG. 1B, the conductor 14 may be made up of a stack of a first and a second transparent conducting oxide (TCO) layer 14A, 14C, and a metal doped silicon dioxide layer 14B sandwiched between the two TCO layers 14A, 14C. Details of the conductor 14 and its manufacturing method may be found in PCT Publication No. WO 2013/010067, the content of which is hereby incorporated by reference in its entirety for all purposes.

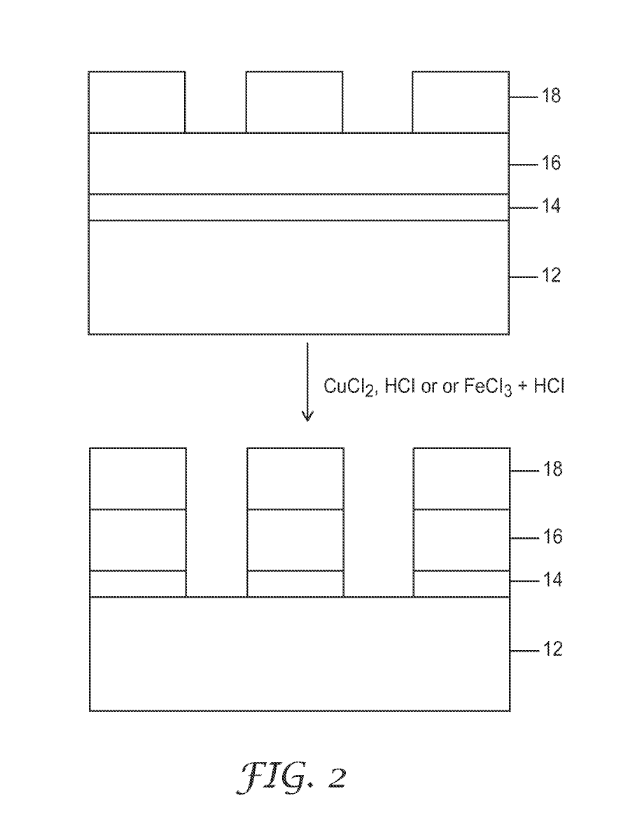

The metal layer 16 and conductor 14 may be patterned simultaneously to define one or more portions of the metal layer 16 and conductor 14 to be removed (FIG. 2). The metal layer 16 and conductor 14 may be patterned, for example, by photolithographic techniques commonly used in the art. In one illustration, a pre-patterned etch stopper or resist 18 may first be disposed on the metal layer 16. In other words, the patterns pre-formed on the etch stopper or resist 18 correspond to the patterns to be transferred to the underlying metal layer 16 and conductor 14, thereby defining one or more portions of the metal layer 16 and conductor 14 to be removed.

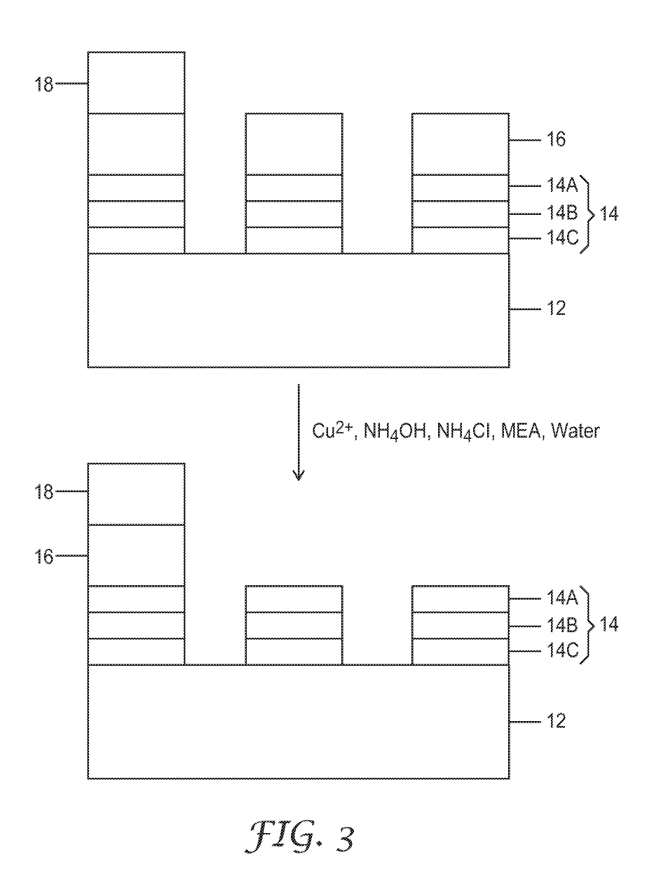

After disposing the etch stopper or resist 18 on the patterned metal layer 16 and conductor 14, the microstructure 10 with etch stopper or resist 18 covering metal interconnect portion (as shown in FIG. 3) is contacted with an etchant formulation including a mixture of cupric halide and a solution of an amine and/or ammonium compound. The etchant formulation removes the defined one or more portions of the metal layer 16, thereby exposing one or more portions of the underlying first TCO layer 14A. Further contact of the etchant formulation with the exposed one or more portions of the underlying first TCO layer 14A does not etch away the exposed one or more portions of the underlying first TCO layer 14A. In other words, the metal layer 16 is selectively etched without affecting the TCO pattern. In certain embodiments where the metal layer 16 is copper and the first TCO layer 14A is indium tin oxide (ITO), the etch ratio of copper to ITO is about 2400:1.

In various embodiments, the etchant formulation may include a mixture of cupric halide and a solution of an amine compound.

In further embodiments, the etchant formulation may include a mixture of cupric halide and a solution of an ammonium compound.

In present context, ammonium compounds are compounds or salts that contain cation ammonium (i.e. NH₄⁺). The ammonium compounds may be in fluid, such as liquid or solution, or in solid form. For example, the ammonium compound may be at least one of, but is not limited to, ammonium halide and ammonium hydroxide.

In present context, amines are organic compounds and functional groups that contain a basic nitrogen atom with a lone pair of electrons. Amines are derivatives of ammonia, wherein one or more hydrogen atoms have been replaced by a substituent such as an alkyl or aryl group. The amine may be primary amine (i.e. NR¹H₂), secondary amine (i.e. NR¹R²H), or tertiary amine (i.e. NR¹R²R³), where each of R¹, R², and R³ is not hydrogen.

Most of existing etching formulations are acid-based, and would etch both the metal layer (se.g. copper) as well as the TCO layer (e.g. indium tin oxide). The present etchant formulation is basic, rather than acidic, and selectively etches copper over ITO. The etchant formulation may include cupric chloride and amine-containing ligands that forms coordination complex with the cupric ion. An aqueous solution of cupric chloride is acidic in nature and etches both copper and ITO. On the other hand, cupric chloride with amine-containing ligands such as NH₃, alkyl amines, alkoxy amines etch copper selectively over ITO. In a specific example, copper (II)-amine complexes were generated by mixing cupric chloride and amine-containing ligands in water to form a complex of general formula Cu²⁺LₙX₂,
where L is the coordinating ligand;
X is halide ion such as Cl⁻, Br⁻, I⁻, F⁻;
n represents number of moles of amine containing ligands and ranges from 2 to 4 based on the coordination mode of the ligand.

The coordinating ligand of the amine compound may be monodentate or bidentate.

The copper-amine complexes undergo redox reaction with copper metal over ITO. Cupric chloride amine complex may be reduced to cuprous amine complex by copper metal. Hence, excessive amounts of cuprous amine complex may be replenished by adding amine compounds. Accordingly, in various embodiments, the etchant formulation may include a mixture of cupric halide and a solution of an amine compound and an ammonium compound. For example at least one of ammonium halide, ammonium hydroxide, monoethanol amine may be added to the etchant formulation.

In embodiments where ammonia solution (i.e. ammonium hydroxide) is present in the etchant formulation, due to rapid evaporation of ammonia, high boiling point (>100° C.) may be used, and water soluble amine compounds may be added, to compensate the ammonia evaporation loss.

Accordingly, in various embodiments, the amine compound may have a boiling point higher than 100° C.

In various embodiments, the amine compound may be at least one of an alkyl amine and an alkoxy amine.

The term “alkyl”, alone or in combination, refers to a fully saturated aliphatic hydrocarbon. In certain embodiments, alkyls are optionally substituted. In certain embodiments, an alkyl comprises 1 to 30 carbon atoms, for example 1 to 20 carbon atoms, wherein (whenever it appears herein in any of the definitions given below) a numerical range, such as “1 to 20” or “C1-C20”, refers to each integer in the given range, e.g. “C1-C20 alkyl” means that an alkyl group comprises only 1 carbon atom, 2 carbon atoms, 3 carbon atoms, etc., up to and including 20 carbon atoms. Examples of alkyl groups include, but are not limited to, methyl, ethyl, n-propyl, isopropyl, n-butyl, isobutyl, sec-butyl, tert-butyl, tert-amyl, pentyl, hexyl, heptyl, octyl and the like.

The term “alkoxy”, alone or in combination, refers to an aliphatic hydrocarbon having an alkyl-O— moiety. In certain embodiments, alkoxy groups are optionally substituted. Examples of alkoxy groups include, but are not limited to, methoxy, ethoxy, propoxy, butoxy and the like. In one embodiment, the amine compound may be monoethanol amine (MEA).

The term “halide” refers to fluoride, chloride, bromide, or iodide. Accordingly, in various embodiments, the cupric halide may be cupric fluoride, cupric chloride, cupric bromide, or cupric iodide. In one embodiment, the cupric halide is cupric chloride.

Likewise, in various embodiments, the ammonium halide may be ammonium fluoride, ammonium chloride, ammonium bromide, or ammonium iodide. In one embodiment, the ammonium halide is ammonium chloride.

It has been found that pH of the etchant formulation, and in particular the ammonium compound such as ammonium hydroxide, may affect the sheet resistance of the TCO layer (see Example 1 below). At low pH and at high pH of the ammonium hydroxide, micro etching of the TCO layer occurs, and this affects the sheet resistance of ITO adversely. Hence, in various embodiments, the pH of the etchant formulation is kept at above 7, such as between about 8.5 and 9.

Concentration of the ammonium halide in the etchant formulation may also affect etching of the TCO layer and the sheet resistance of the TCO layer (see Example 1 below). Accordingly, in various embodiments, the mole ratio of cupric halide to the ammonium compound may be kept at 1:4 or lower, such as 1:5, 1:6, or 1:7.

The microstructure may be immersed in the etchant formulation at temperatures higher than room temperature. For example, the etchant formulation may be heated to between 50° C. and 100° C. prior to contacting the microstructure, such as 50° C., 55° C., 60° C., 65° C., 70° C., 75° C., 80° C., 85° C., 90° C., 95° C., or 100° C. Doing so may help to enhance the rate of etching of the metal layer of the microstructure. The contact period may be between 30 seconds and 1,200 seconds. For example, for a 12 μm thick copper layer, the contact period, i.e. etching time, may be about 35 seconds to 90 seconds.

In various embodiments, the first and second TCO layers 14A, 14C may be made up of indium tin oxide (ITO), fluorine doped tin oxide (FTO), or indium doped zinc oxide (IZO). The first and second TCO layers 14A, 14C may be the same material or different materials from one another. For example, in one embodiment the first and second TCO layers 14A, 14C are each ITO.

The first and second TCO layers 14A, 14C can have the same or different thicknesses. For example, suitable thickness for the first and second TCO layers 14A, 14C may include 50 nm or less, such as 45 nm, 40 nm, 35 nm, 30 nm, 25 nm, 20 nm, or less. In illustrative embodiments, the first and the second TCO layers 14A, 14C thicknesses are the same, for example, each having a thickness of between about 20-25 nm.

According to various embodiments, the metal doped silicon dioxide 14B sandwiched between the first and the second TCO layers 14A, 14C may be aluminium doped silicon dioxide (SiAlOₓ). In alternative embodiments, the metal doped silicon dioxide 14B sandwiched between the first and the second TCO layers 14A, 14C may be silver or zinc doped silicon dioxide. The metal doped silicon dioxide 14B can have a thickness of about 50 nm or less, such as 45 nm, 40 nm, 35 nm, 30 nm, or less.

In certain embodiments, the conductor 14 may be made up of a stack of a first ITO layer 14A of about 20-25 nm thickness, a second ITO layer 14C of about 20-25 nm thickness, and a SiAlOₓ layer 14B sandwiched between the two ITO layers 14A, 14C, the SiAlOₓ layer 14B having a thickness of between about 40-45 nm.

In various embodiments, the metal layer 16 may be copper (Cu), nickel (Ni), silver (Ag), palladium (Pd), gold (Au), molybdenum (Mo), titanium (Ti), or an alloy thereof.

In one embodiment, the metal layer 16 may include Cu.

In order that the invention may be readily understood and put into practical effect, particular embodiments will now be described by way of the following non-limiting examples.

### EXAMPLES

### Example 1

Table 1 lists the etching parameters/conditions used in this example.

TABLE 1
Bath Conditions

| CuCl₂•2H₂O | 1.8 | Moles/lit |
|---|---|---|
| NH₄Cl | 6.5 | moles/lit |
| 28% Ammonium hydroxide | 700 | ml |
| pH | 8.5 | |
| Temperature | 50° | C. |
| Etching time of 12 um copper | 30 | seconds |

| | |
|---|---|
| % change in resistance of ITO | 7% |
| after 3 minutes | |

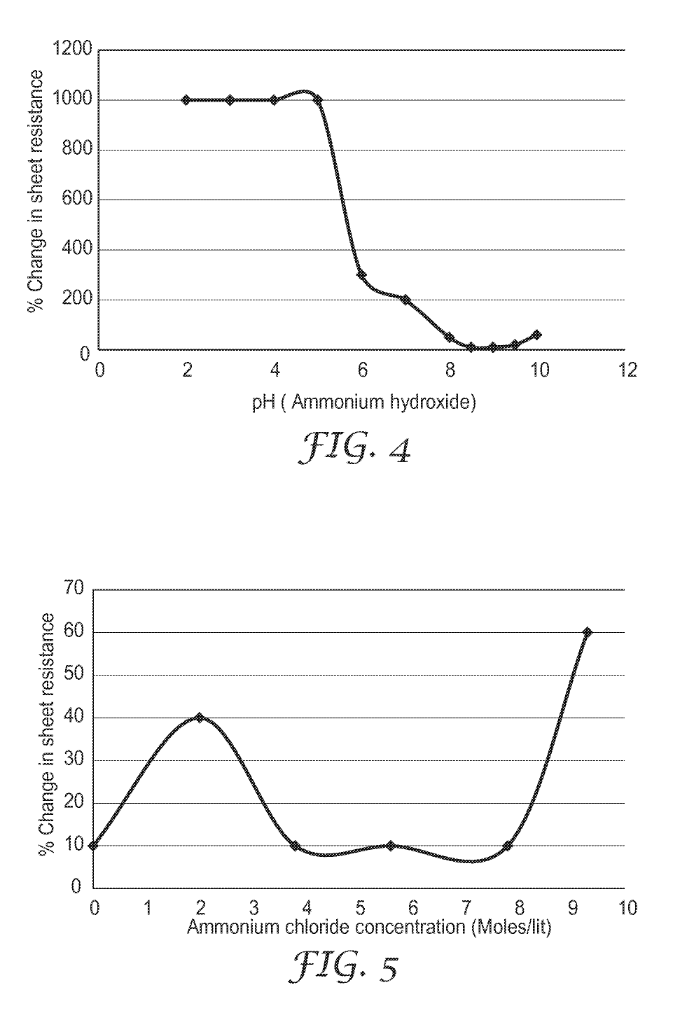

Copper concentration is not a limiting factor for the etching reaction. Cupric chloride salt in the range of 0.5 to 1.8 moles/litter was used. Lower and higher pH ammonium hydroxide leads to micro etching of ITO and affects the sheet resistance of ITO. Experiments were carried out measuring sheet resistance of ITO before and after immersing in etchant solutions of cupric chloride and ammonium hydroxide mixture. Samples were immersed for 1 minute at 50° C. and washed with deionized (DI) water thoroughly and air dried before measuring sheet resistance. As shown in FIG. 4, sheet resistance changes with respect to pH. At lower pH (below 6), ITO was etched and change in sheet resistance (ΔR) was minimal at a higher pH of 8-9. Increase in ΔR was observed beyond a pH of 9. Hence, ammonium hydroxide level was kept at a pH in the 8.5 to 9 range to minimize ITO etching.

Etching of ITO also depends on the concentration of ammonium chloride. Excess amount of ammonium chloride in the solution leads to micro etching ITO. Ammonium chloride in the range of 4-8 moles/litter gives the desired effect of low ΔR (see FIG. 5). Mole ratios of cupric chloride to ammonium chloride were kept at 1:4 and below.

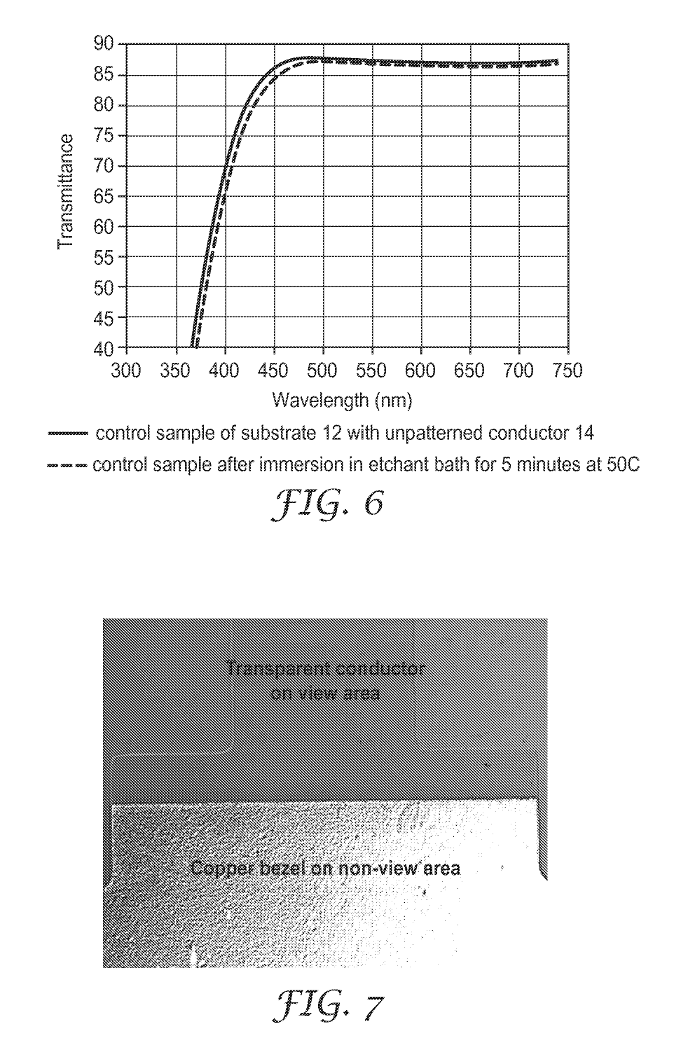

Aside from sheet resistance values, optical properties of ITO film were measured before and after immersing the sample in the above bath. As shown in the chart in FIG. 6, the transmittance values do not change after immersing ITO sample for 5 minutes.

### Example 2

One of the issues with ammonium hydroxide is that it evaporates in a rapid manner and leads to precipitation of components. It requires the constant addition of ammonium hydroxide to compensate for evaporation and prevent precipitate formation. Water soluble and high boiling point amines can solve the above-mentioned issues. Monoethanolamine (MEA) with a boiling point 170° C. and better miscibility with water is a suitable ligand. It can form a coordination bond with copper ions. The etching rate of copper depends on the concentration of MEA as shown in Table 2.

TABLE 2

| | | 12 um copper etching |
|---|---|---|
| MEA (Moles/lit) | NH₄OH (vol/lit) | time (s) |
| 1.6 | 500 | 35 |
| 3.2 | 400 | 45 |
| 4.8 | 400 | 90 |
| 8 | 0 | 120 |
| 12 | 0 | 780 |
| 13.6 | 0 | 1080 |

The formulation in Table 3 provides longer bath life with minimal use of ammonium hydroxide and faster etching rate.

TABLE 3
Bath Conditions

| CuCl₂•2H₂O | 1.5 | Moles/lit |
|---|---|---|
| NH₄Cl | 6 | moles/lit |
| 28% Ammonium hydroxide | 700 | ml |
| MEA | 1-5 | moles/lit |
| pH | 8.5 | |
| Temperature | 50 | C. |
| Etching time of 12 um | 35-90 | sec |
| copper | | |

| | |
|---|---|
| % change in resistance of | 7% |
| ITO after 3 minutes | |

Optical values of the samples were verified before and after immersing the samples in the etchant solution for 5 minutes. As shown in Table 3A, transmittance, haze and clarity of the substrate 12 with conductor layer 14 were not generally affected by these chemical formulation.

TABLE 3A

| | Transmittance | Haze | Clarity |
|---|---|---|---|
| Control sample | 89.6 | 2.29 | 99.8 |
| After immersion in bath for 5 minutes | 89.1 | 2.26 | 99.8 |

Copper was sputtered on a conductive transparent conductor. Copper and conductive transparent conductor layers were then patterned simultaneously (see PCT Publication No. WO 2013/010067). In this method, the touch view area, which had patterned transparent conductor and a touch non-view area, which had conductive metal bezel pattern, were patterned simultaneously. Finally, copper in the bezel area was covered by dry film photomask and the copper on the touch view area was left open for etching purpose. Copper on the touch view area was selectively etched from the ITO using present etchant (see FIG. 7). A sensor prepared by this method can be used to make capacitive type touch sensor.

By “comprising” it is meant including, but not limited to, whatever follows the word “comprising”. Thus, use of the term “comprising” indicates that the listed elements are required or mandatory, but that other elements are optional and may or may not be present.

By “consisting of” is meant including, and limited to, whatever follows the phrase “consisting of”. Thus, the phrase “consisting of” indicates that the listed elements are required or mandatory, and that no other elements may be present.

The inventions illustratively described herein may suitably be practiced in the absence of any element or elements, limitation or limitations, not specifically disclosed herein. Thus, for example, the terms “comprising”, “including”, “containing”, etc. shall be read expansively and without limitation. Additionally, the terms and expressions employed herein have been used as terms of description and not of limitation, and there is no intention in the use of such terms and expressions of excluding any equivalents of the features shown and described or portions thereof, but it is recognized that various modifications are possible within the scope of the invention claimed. Thus, it should be understood that although the present invention has been specifically disclosed by preferred embodiments and optional features, modification and variation of the inventions embodied herein may be resorted to by those skilled in the art, and that such modifications and variations are considered to be within the scope of this invention.

By “about” in relation to a given numerical value, such as for temperature and period of time, it is meant to include numerical values within 10% of the specified value.

The invention has been described broadly and generically herein. Each of the narrower species and sub-generic groupings falling within the generic disclosure also form part of the invention. This includes the generic description of the invention with a proviso or negative limitation removing any subject matter from the genus, regardless of whether or not the excised material is specifically recited herein.

Other embodiments are within the following claims and non-limiting examples. In addition, where features or aspects of the invention are described in terms of Markush groups, those skilled in the art will recognize that the invention is also thereby described in terms of any individual member or subgroup of members of the Markush group.

1. A method of selectively etching a portion of a metal layer of a microstructure, wherein the microstructure is comprised of the metal layer disposed on a transparent conducting oxide (TCO) layer, the method comprising contacting the microstructure with an etchant formulation comprising a mixture of cupric halide and a solution of an amine and/or ammonium compound.

2. The method of claim 1, wherein the ammonium compound is at least one of an ammonium halide and ammonium hydroxide.

3. The method of claim 2, wherein the ammonium compound is ammonium chloride and ammonium hydroxide.

4. The method of claim 1, wherein the amine compound has a boiling point higher than 100° C.

5. The method of claim 1, wherein the amine compound is at least one of an alkyl amine and an alkoxy amine.

6. The method of claim 5, wherein the amine compound is an alkoxy amine.

7. The method of claim 6, wherein the amine compound is monoethanol amine.

8. The method of claim 1, wherein the amine compound is a monodentate ligand.

9. The method of claim 1, wherein the amine compound is a bidentate ligand.

10. The method of claim 1, wherein the etchant formulation has a pH above 7.

11. The method of claim 10, wherein the pH of the etchant formulation is between about 8.5 and 9.

12. The method of claim 1, wherein a mole ratio of cupric halide to the ammonium compound is about 1:4.

13. The method of claim 1, wherein the etchant formulation is heated to between about 50° C. and about 100° C. prior to contacting the microstructure.

14. The method of claim 1, wherein the etchant formulation is contacted with the microstructure of a period of between about 30 seconds and about 1,200 seconds.

15. The method of claim 1, wherein the metal layer is comprised of copper (Cu), nickel (Ni), silver (Ag), palladium (Pd), gold (Au), molybdenum (Mo), titanium (Ti), or an alloy thereof.

16. The method of claim 1, wherein the TCO layer is comprised of indium tin oxide (ITO).

17. The method of claim 1, wherein the metal layer is patterned with a resist.
